(19) United States
(12) Patent Application Publication
(10) Pub. No.: US 2007/0090366 A1
(43) Pub. Date: Apr. 26, 2007

(54) TFT array substrate and photo-masking method for fabricating same

(75) Inventors: Chao-Yi Hung, Miao-Li (TW); Chih-Hao Chen, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/586,855

(22) Filed: Oct. 26, 2006

(30) Foreign Application Priority Data
Oct. 26, 2005 (CN) 200510100782.7

(51) Int. Cl. H01L 29/04; H01L 21/84

(52) U.S. Cl. 257/72; 438/149

(57) ABSTRACT

An exemplary method for fabricating a thin film transistor (TFT) array substrate (200) includes: forming a transparent conductive layer (202) and a gate metal layer (203) on an insulating substrate (201); forming a photo-resist layer (231) on the gate metal layer; exposing the photo-resist layer using a photo-mask with a predetermined pattern; developing the photo-resist layer to form a photo-resist pattern; and etching the transparent conductive layer and the gate metal layer using the photo-resist pattern as a mask to form a plurality of gate electrodes (213) and a plurality of pixel electrodes (212). Compared to the conventional method, in the above-described exemplary method for fabricating the TFT array substrate, only one photo-mask process is used to form the gate electrodes and the pixel electrodes, thus saving one photo-mask process. Therefore, a simplified method at a reduced cost is provided.

### FIELD OF THE INVENTION

The present invention relates to thin film transistor (TFT) array substrates used in liquid crystal displays (LCDs) and methods for fabricating these substrates, and particularly to a TFT array substrate and a method for fabricating the substrate which efficiently uses minimal photo-masking.

### GENERAL BACKGROUND

A typical liquid crystal display (LCD) is capable of displaying a clear and sharp image through millions of pixels that make up the complete image. The liquid crystal display has thus been applied to various electronic equipment in which messages or pictures need to be displayed, such as mobile phones and notebook computers. A liquid crystal panel is a major component of the LCD, and generally includes a thin film transistor (TFT) array substrate, a color filter substrate opposite to the TFT array substrate, and a liquid crystal layer sandwiched between the two substrates.

Referring to FIG. 12, part of a typical TFT array substrate is shown. The TFT array substrate 100 includes a substrate 101, a gate electrode 102 formed on the substrate 101, a gate insulating layer 103 formed on the substrate 101 having the gate electrode 102, a semiconductor layer 104 formed on the gate insulating layer 103, a source electrode 105 and a drain electrode 106 formed on the gate insulating layer 103 and the semiconductor layer 104, a passivation layer 107 formed on the gate insulating layer 103, the source electrode 105 and the drain electrode 106, and a pixel electrode 108 formed on the passivation layer 107.

Referring to FIG. 13, this is a flowchart summarizing a typical method of fabricating the TFT array substrate 100. For simplicity, the flowchart and the following description are couched in terms that relate to the part of the TFT array substrate 100 shown in FIG. 12. The method includes: step S10, forming a gate metal layer; step S11, forming a gate electrode; step S12, forming a gate insulating layer and an amorphous silicon (a-Si) and doped a-Si layer; step S13, forming a semiconductor layer on the gate insulating layer; step S14, forming a source/drain metal layer; step S15, forming source/drain electrodes; step S16, forming a passivation material layer; step S17, forming a passivation layer; step S18, forming a transparent conductive layer; and step S19, forming a pixel electrode.

In step S10, an insulating substrate is provided. The substrate may be made from glass or quartz. A gate metal layer and a first photo-resist layer are formed on the substrate.

In step S11, the first photo-resist layer is exposed by a first photo-mask, and then is developed, thereby forming a first photo-resist pattern. The gate metal layer is etched, thereby forming a pattern of the gate electrode 102, which corresponds to the first photo-resist pattern. The residual first photo-resist layer is then removed.

In step S12, a gate insulating layer 103, an a-Si and doped a-Si layer, and a second photo-resist layer are sequentially formed on the substrate 101 having the gate electrode 102.

In step S13, the second photo-resist layer is exposed by a second photo-mask, and then is developed, thereby forming a second photo-resist pattern. The a-Si and doped a-Si layer is etched, thereby forming a pattern of the semiconductor layer 104, which corresponds to the second photo-resist pattern. The residual second photo-resist layer is then removed.

In step S14, a source/drain metal layer and a third photo-resist layer are sequentially formed on the semiconductor layer 104.

In step S15, the third photo-resist layer is exposed by a third photo-mask, and then is developed, thereby forming a third photo-resist pattern. The source/drain metal layer is etched, thereby forming a pattern of the source electrode 105 and the drain electrode 106, which corresponds to the third photo-resist pattern. The residual third photo-resist layer is then removed.

In step S16, a passivation material layer and a fourth photo-resist layer are sequentially formed on the substrate 101 having the three electrodes 102, 105, 106 formed thereon.

In step S17, the fourth photo-resist layer is exposed by a fourth photo-mask, and then is developed, thereby forming a fourth photo-resist pattern. The passivation material layer is etched, thereby forming a pattern of the passivation layer 107, which corresponds to the fourth photo-resist pattern. The residual fourth photo-resist layer is then removed.

In step S18, a transparent conductive layer and a fifth photo-resist layer are sequentially formed on the passivation layer 107.

In step S19, the fifth photo-resist layer is exposed by a fifth photo-mask, and then is developed, thereby forming a fifth photo-resist pattern. The transparent conductive layer is etched, thereby forming a pattern of the pixel electrode 108, which corresponds to the fifth photo-resist pattern. The residual fifth photo-resist layer is then removed.

The method includes five photo-mask processes, each of which is rather complicated and costly. Therefore, the method of fabricating the TFT array substrate 100 is correspondingly complicated and costly.

What is needed, therefore, is a method for fabricating a TFT array substrate that can overcome the above-described problems. What is also needed is a TFT array substrate fabricated by the above method.

### SUMMARY

In one embodiment, a method for fabricating a thin film transistor array substrate includes: forming a transparent conductive layer and a gate metal layer on an insulating substrate; forming a photo-resist layer on the gate metal layer; exposing the photo-resist layer using a photo-mask with a predetermined pattern; developing the photo-resist layer to form a photo-resist pattern; and etching the transparent conductive layer and the gate metal layer using the photo-resist pattern as a mask to form a plurality of gate electrodes and a plurality of pixel electrodes.

Other advantages and novel features will become more apparent from the following detailed description when taken in conjunction with the accompanying drawings.

### BRIEF DESCRIPTION OF THE DRAWINGS

FIG. 1 is a schematic, side cross-sectional view of part of a TFT array substrate according to an exemplary embodiment of the present invention.

FIG. 2 is a flowchart summarizing an exemplary method for fabricating the TFT array substrate of FIG. 1.

FIG. 3 is a schematic, side cross-sectional view relating to a step of providing a substrate and forming a transparent conductive layer, a gate metal layer and a first photo-resist layer on the substrate according to the method of FIG. 2.

FIG. 4 is a schematic, side cross-sectional view relating to a next step of forming a gate electrode and a pixel electrode according to the method of FIG. 2.

FIG. 5 is a schematic, side cross-sectional view relating to a next step of forming a gate insulating layer on the substrate having the gate electrode and the pixel electrode according to the method of FIG. 2.

FIG. 6 is a schematic, side cross-sectional view relating to a next step of forming a semiconductor layer on the gate insulating layer according to the method of FIG. 2.

FIG. 7 is a schematic, side cross-sectional view relating to a next step of forming a third photo-resist layer on the semiconductor layer and the gate insulating layer according to the method of FIG. 2.

FIG. 8 is a schematic, side cross-sectional view relating to a next step of forming a contact hole through the gate insulating layer according to the method of FIG. 2.

FIG. 9 is a schematic, side cross-sectional view relating to a next step of forming a source/drain metal layer and a fourth photo-resist layer on the gate insulating layer and the semiconductor layer according to the method of FIG. 2.

FIG. 10 is a schematic, side cross-sectional view relating to a next step of forming source/drain electrodes on the gate insulating layer and the semiconductor layer according to the method of FIG. 2.

FIG. 11 is a schematic, side cross-sectional view relating to a next step of forming a passivation layer on the source/drain electrodes and the gate insulating layer according to the method of FIG. 2.

FIG. 12 is a schematic, side cross-sectional view of part of a conventional TFT array substrate.

FIG. 13 is a flowchart summarizing a conventional method of fabricating the TFT array substrate of FIG. 12.

### DETAILED DESCRIPTION OF PREFERRED EMBODIMENTS

Referring to FIG. 1, part of a thin film transistor (TFT) array substrate according to an exemplary embodiment of the present invention is shown. The TFT array substrate 200 includes an insulating substrate 201, a pixel electrode 212 and a transparent conductive layer 202 formed on the substrate 201, a gate electrode 213 formed on the transparent conductive layer 202, a gate insulating layer 204 formed on the gate electrode 213, the pixel electrode 212 and the exposed substrate 201, a semiconductor layer 215 formed on the gate insulating layer 204, source/drain electrodes 216 formed on the semiconductor layer 215 and the gate insulating layer 204, and a passivation layer 207 formed on the source/drain electrodes 216 and the gate insulating layer 204.

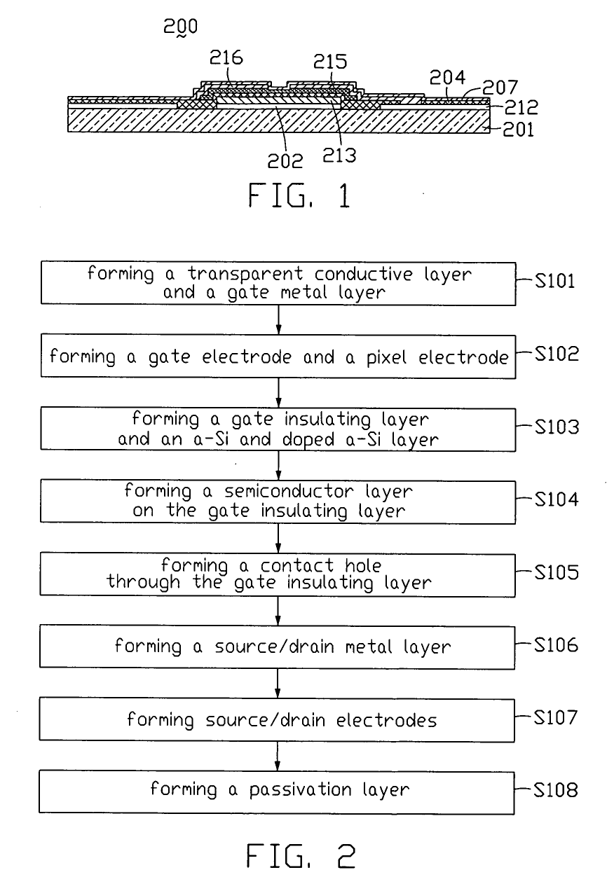

Referring to FIG. 2, this is a flowchart summarizing an exemplary method for fabricating the TFT array substrate 200. For simplicity, the flowchart and the following description are couched in terms that relate to the part of the TFT array substrate 200 shown in FIG. 2. The method includes: step S101, forming a transparent conductive layer and a gate metal layer; step S102, forming a gate electrode and a pixel electrode; step S103, forming a gate insulating layer and an amorphous silicon (a-Si) and doped a-Si layer; step S104, forming a semiconductor layer on the gate insulating layer; step S105, forming a contact hole through the gate insulating layer; step S106, forming a source/drain metal layer; step S107, forming source/drain electrodes; and step S108, forming a passivation layer.

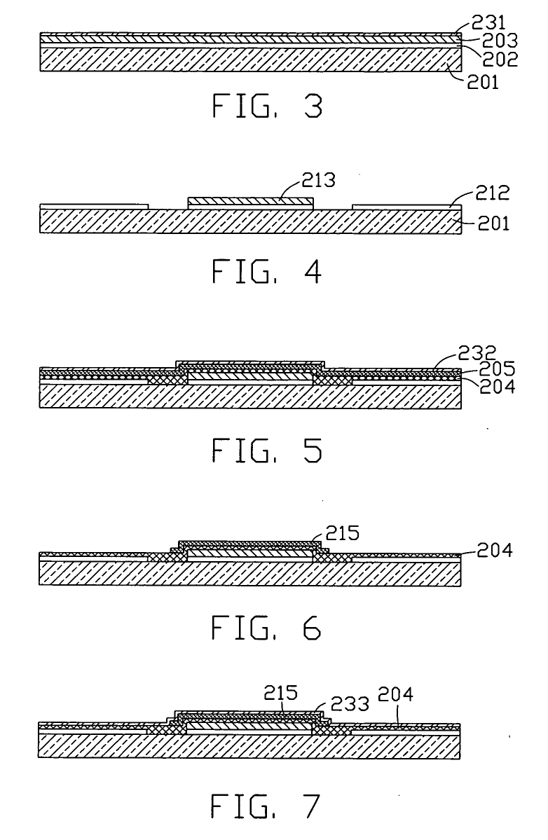

In step S101, referring to FIG. 3, an insulating substrate 201 is provided. The substrate 201 may be made of glass or quartz. A transparent conductive layer 202, a gate metal layer 203, and a first photo-resist layer 231 are sequentially formed on the substrate 201. The transparent conductive layer 202 may be made from indium tin oxide (ITO) or indium zinc oxide (IZO). The gate metal layer 203 may be made from material including any one or more items selected from the group consisting of aluminum (Al), molybdenum (Mo), copper (Cu), chromium (Cr), and tantalum (Ta).

In step S102, a light source (not shown) and a first photo-mask (not shown) are used to expose the first photo-resist layer 231. Then the exposed first photo-resist layer 231 is developed, thereby forming a first photo-resist pattern. Using the first photo-resist pattern as a mask, the gate metal layer 203 and the transparent conductive layer 202 are etched, thereby forming the gate electrode 213 and the pixel electrode 212, as shown in FIG. 4. The residual first photo-resist layer 231 is removed, and the substrate 201 is cleaned and dried.

Because the gate metal layer 203 and the transparent conductive layer 202 are adjacent each other, and the gate electrode 213 and the pixel electrode 212 do not overlap each other, only one photo-mask process is needed to form the gate electrode 213 and the pixel electrode 212. Compared to the above-described conventional method, one photo-mask process is saved, thus providing a simplified method and decreasing costs.

In step S103, referring to FIG. 5, a gate insulating layer 204 is formed on the substrate 201 having the gate electrode 213 and the pixel electrode 212 by a chemical vapor deposition (CVD) process. In this process, silane (SiH₄) reacts with alkaline air (NH₄) to obtain silicon nitride (SiNₓ), a material of the gate insulating layer 204. An amorphous silicon (a-Si) material layer is formed on the gate insulating layer 204 by a CVD process. The a-Si layer is doped, thereby forming an a-Si and doped a-Si layer 205. A second photo-resist layer 232 is formed on the a-Si and doped a-Si layer 205.

In step S104, the light source and a second photo-mask (not shown) are used to expose the second photo-resist layer 232. Then the exposed second photo-resist layer 232 is developed, thereby forming a second photo-resist pattern. Using the second photo-resist pattern as a mask, the a-Si and doped a-Si layer 205 is dry etched, thereby forming the semiconductor layer 215, as shown in FIG. 6. The residual second photo-resist layer 232 is removed.

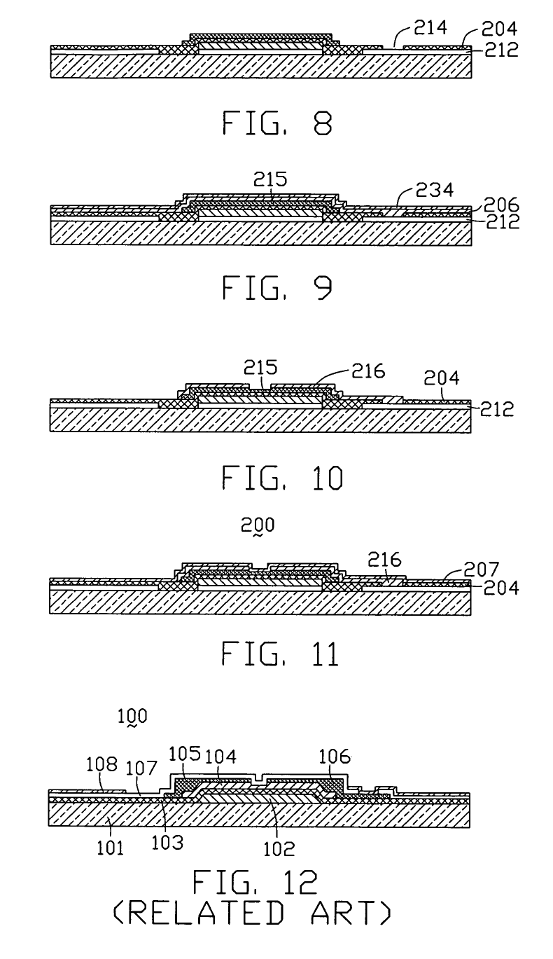

In step S105, referring to FIG. 7, a third photo-resist layer 233 is formed on the semiconductor layer 215 and the gate insulating layer 204. The light source and a third photo-mask (not shown) are used to expose the third photo-resist layer 233. Then the exposed third photo-resist layer 233 is developed, thereby forming a third photo-resist pattern. Using the third photo-resist pattern as a mask, the gate insulating layer 204 is etched, thereby forming a contact hole 214 through the gate insulating layer 204, as shown in FIG. 8. The residual third photo-resist layer 233 is removed.

In step S106, referring to FIG. 9, a source/drain metal layer 206 and a fourth photo-resist layer 234 are sequentially formed on the gate insulating layer 204 and the semiconductor layer 215. The source/drain metal layer 206 may be made from molybdenum or molybdenum alloy. With this configuration, the source/drain metal layer 206 is electrically connected to the pixel electrode 212 via the contact hole 214.

In step S107, the light source and a fourth photo-mask (not shown) are used to expose the fourth photo-resist layer 234. Then the exposed fourth photo-resist layer 234 is developed, thereby forming a fourth photo-resist pattern. Using the fourth photo-resist pattern as a mask, the source/drain metal layer 206 is etched, thereby forming source/drain electrodes 216, as shown in FIG. 10. The residual fourth photo-resist layer 234 is removed.

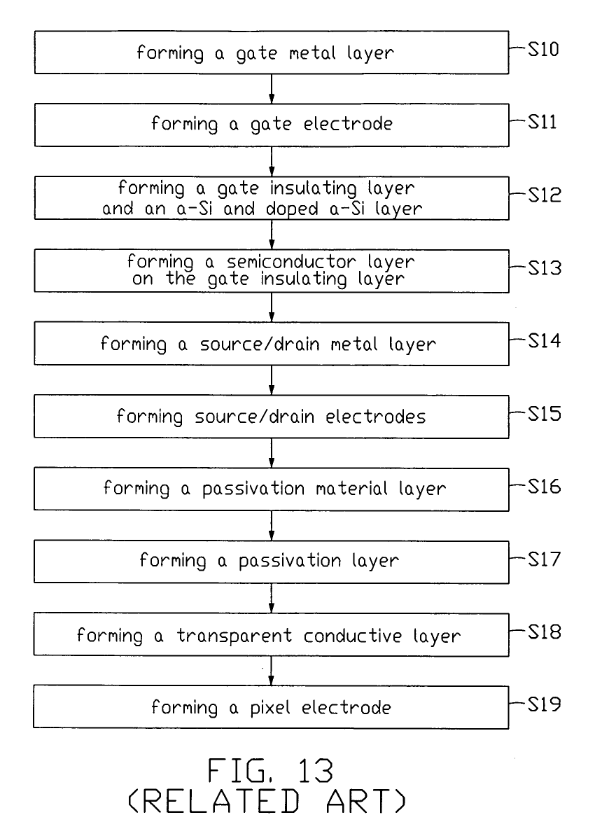

In step S108, referring to FIG. 11, a passivation layer 207 is formed on the source/drain electrodes 216 and the gate insulating layer 204, thereby obtaining the TFT array substrate 200.

In summary, compared to the above-described conventional method, in the above-described exemplary method for fabricating the TFT array substrate 200, only one photo-mask process is used to form the gate electrode 213 and the pixel electrode 212, thus saving one photo-mask process. Therefore, a simplified method at a reduced cost is provided.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A method for fabricating a thin film transistor (TFT) array substrate, the method comprising:
forming a transparent conductive layer and a gate metal layer on an insulating substrate;
forming a photo-resist layer on the gate metal layer;
exposing the photo-resist layer using a photo-mask with a predetermined pattern;
developing the photo-resist layer to form a photo-resist pattern; and
etching the transparent conductive layer and the gate metal layer using the photo-resist pattern as a mask to form a plurality of gate electrodes and a plurality of pixel electrodes.

2. The method as claimed in claim 1, wherein the transparent conductive layer is made from indium tin oxide or indium zinc oxide.

3. The method as claimed in claim 1, wherein the gate metal layer is made from material including any one or more items selected from the group consisting of aluminum, molybdenum, copper, chromium, and tantalum.

4. The method as claimed in claim 1, further comprising forming a gate insulating layer on the substrate having the gate electrodes and the pixel electrodes.

5. The method as claimed in claim 4, further comprising forming a semiconductor layer on the gate insulating layer.

6. The method as claimed in claim 5, further comprising forming a plurality of contact holes through the gate insulating layer.

7. The method as claimed in claim 6, further comprising forming source/drain electrodes on the semiconductor layer and the gate insulating layer, wherein each of the drain electrodes is electrically connected to a corresponding one of the pixel electrodes via a corresponding one of the contact holes.

8. The method as claimed in claim 1, wherein the substrate is made from glass or quartz.

9. A method for fabricating a thin film transistor (TFT) array substrate, the method comprising:
providing an insulating substrate;
forming a transparent conductive layer and a gate metal layer on the substrate;
forming a plurality of gate electrodes and a plurality of pixel electrodes using a first photo-mask process;
forming a gate insulating layer on the substrate having the gate electrodes and the pixel electrodes;
forming a semiconductor layer on the gate insulating layer using a second photo-mask process;
forming a plurality of contact holes through the gate insulating layer using a third photo-mask process; and
forming source/drain electrodes on the semiconductor layer and the gate insulating layer using a fourth photo-mask process.

10. The method as claimed in claim 9, further comprising forming a passivation layer on the source/drain electrodes and the gate insulating layer.

11. The method as claimed in claim 9, wherein the substrate is made from glass or quartz.

12. The method as claimed in claim 9, wherein the transparent conductive layer is made from indium tin oxide or indium zinc oxide.

13. The method as claimed in claim 9, wherein the gate metal layer is made from material including any one or more items selected from the group consisting of aluminum, molybdenum, copper, chromium, and tantalum.

14. A thin film transistor (TFT) array substrate comprising: an insulating substrate;
a transparent conductive layer and a plurality of pixel electrodes formed on the substrate;
a plurality of gate electrodes formed on the transparent conductive layer;
a gate insulating layer formed on the gate electrodes, the pixel electrodes, and the substrate;
a semiconductor layer formed on the gate insulating layer; and
source/drain electrodes formed on the semiconductor layer and the gate insulating layer, wherein each of the drain electrodes connects to a corresponding one of the pixel electrodes.

15. The TFT array substrate as claimed in claim 14, further comprising a passivation layer formed on the source/drain electrodes and the gate insulating layer.

16. The TFT array substrate as claimed in claim 14, wherein the substrate is made from glass or quartz.

17. The TFT array substrate as claimed in claim 14, wherein the transparent conductive layer is made from indium tin oxide or indium zinc oxide.

18. The TFT array substrate as claimed in claim 14, wherein the gate metal layer is made from material including any one or more items selected from the group consisting of aluminum, molybdenum, copper, chromium, and tantalum.
